(19) United States
(12) Patent Application Publication
(10) Pub. No.: US 2012/0228701 A1
(43) Pub. Date: Sep. 13, 2012

(54) SEMICONDUCTOR DEVICE AND MANUFACTURING METHOD THEREOF

(75) Inventor: Hiroki SASAKI, Yokohama-shi (JP)

(73) Assignee: KABUSHIKI KAISHA TOSHIBA, Tokyo (JP)

(21) Appl. No.: 13/363,752

(22) Filed: Feb. 1, 2012

(30) Foreign Application Priority Data
Mar. 8, 2011 (JP) 2011-050474

(51) Int. Cl. H01L 29/78; H01L 21/336

(52) U.S. Cl. 257/330; 438/270; 257/E29.262; 257/E21.41

(57) ABSTRACT

In accordance with an embodiment, a semiconductor device includes a semiconductor layer of a first conductivity type with a recess in the surface of the semiconductor layer, a pocket region of the first conductivity type in the semiconductor layer, a source region of a second conductivity type in the semiconductor layer, a drain region of the first conductivity type in the semiconductor layer, a gate insulating film over the surface of the recess, and a gate electrode. The second conductivity type is different from the first conductivity type. The pocket region includes a part under the surface of the recess. The source region is located adjacent to the pocket region. The drain region is located away from the source region and the pocket region. The gate electrode is configured to fill the recess via the gate insulating film.

### CROSS REFERENCE TO RELATED APPLICATIONS

This application is based upon and claims the benefit of priority from the prior Japanese Patent Application No. 2011-050474, filed on Mar. 8, 2011, the entire contents of which are incorporated herein by reference.

1. Field

Embodiments described herein relate generally to a semiconductor device and a manufacturing method thereof.

2. Background

Recently, a tunnel transistor has been under study as one metal insulation semiconductor field effect transistor (MISFET). The tunnel transistor uses tunneling of electrons to switch operation.

However, the problem of the tunnel transistor is that a current value is lower in contrast with an operating voltage than in a conventional MISFET because of a high resistance value resulting from electron tunneling during operation.

### BRIEF DESCRIPTION OF THE DRAWINGS

FIG. 1 is a schematic sectional view of a tunnel transistor according to a first embodiment;

FIG. 2 is a schematic sectional view of a tunnel transistor according to a comparative example;

FIGS. 3A to 3F are schematic sectional views explaining a method of manufacturing the tunnel transistor shown in FIG. 1;

FIG. 4 is a schematic sectional view of a tunnel transistor according to a second embodiment;

FIG. 5 is a schematic sectional view of a tunnel transistor according to a third embodiment;

FIGS. 6A to 6F are schematic sectional views explaining a method of manufacturing the tunnel transistor shown in FIG. 5; and

FIG. 7 is a schematic sectional view of a tunnel transistor according to a fourth embodiment.

### DETAILED DESCRIPTION

In accordance with an embodiment, a semiconductor device includes a semiconductor layer of a first conductivity type with a recess in the surface of the semiconductor layer, a pocket region of the first conductivity type in the semiconductor layer, a source region of a second conductivity type in the semiconductor layer, a drain region of the first conductivity type in the semiconductor layer, a gate insulating film over the surface of the recess, and a gate electrode. The second conductivity type is different from the first conductivity type. The pocket region includes a part under the surface of the recess. The source region is located adjacent to the pocket region. The drain region is located away from the source region and the pocket region. The gate insulating film includes first and second parts. The first part faces an interface between the source region and the pocket region. The second part faces the first part across the recess. The gate electrode is configured to fill the recess via the gate insulating film.

Embodiments will now be explained with reference to the accompanying drawings. Like components are given like reference numbers throughout the drawings, and are not repeatedly described.

### (1) First Embodiment

(a) Structure of Semiconductor Device

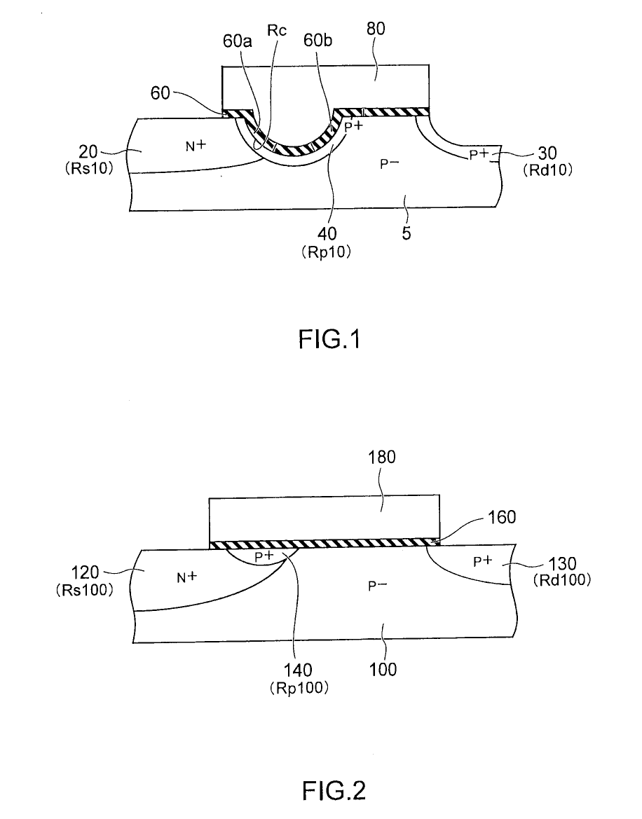

FIG. 1 is a schematic sectional view of a tunnel transistor according to the first embodiment. The present embodiment is characterized by the shape of a pocket which is formed adjacent to a source in a region between the source and a drain and which serves as a supply source of electrons tunneling into the source from an interface with the source (a supply source of holes to the drain). This will be explained below in order.

The tunnel transistor shown in FIG. 1 includes a P− type substrate 5, an N+ impurity diffusion layer 20, a P+ impurity diffusion layer 30, a P+ impurity diffusion layer 40, a gate oxide film 60, and a gate 80. The N+ impurity diffusion layer 20 is formed in a source region Rs10 and serves as a source. The P+ impurity diffusion layer 30 is formed in a drain region Rd10 and serves as a drain. The P+ impurity diffusion layer 40 is formed in a pocket region Rp10 adjacent to the source region Rs10 and serves as a pocket.

The P+ Impurity diffusion layer 40 is formed in the surface layer of the substrate 5 to be substantially as deep as the N+ impurity diffusion layer 20, and has a recess structure with a recess Rc.

The gate oxide film 60 is formed over the surface of the recess Rc.

The gate oxide film 60 at least includes a first part 60a and a second part 60b. The first part 60a faces the interface between the N+ impurity diffusion layer 20 and the P+ Impurity diffusion layer 40. The second part 60a faces the first part 60a across the recess Rc.

The gate 80 is formed on the substrate 5 via the gate oxide film 60 so as to fill the recess Rc, and is therefore shaped to protrude downward (toward the substrate).

In the present embodiment, the N+ impurity diffusion layer 20, the P+ impurity diffusion layer 40, and the P+ impurity diffusion layer 30 correspond to, for example, first to third impurity diffusion layers, respectively. The P-type and the N-type correspond to, for example, first and second conductivity types, respectively.

As a comparative example, a schematic sectional view of a tunnel transistor obtained as a result of a simulation is shown in FIG. 2. The transistor according to the comparative example is simulated to include an N+ impurity diffusion layer 120 which is located in a source region Rs100 of the surface layer of a substrate 100 and which serves as a source, a P+ impurity diffusion layer 130 which is located in a drain region Rd100 and which serves as a drain, a P+ impurity diffusion layer 140 which is located in a pocket region Rp100 provided in the vicinity of the source region Rs100 and which serves as a pocket, a gate oxide film 160, and a gate 180.

However, the tunnel transistor shown in FIG. 2 is not actually produced yet. The reason is that it is extremely difficult to form a high-concentration impurity diffusion layer in an extremely shallow region such as the pocket region Rp100.

According to the present embodiment, the P+ impurity diffusion layer 40 has the recess structure, so that the pocket can be easily formed as described later. As a result, a practical tunnel transistor can be provided. The pocket as deep as the N+ impurity diffusion layer 20 can also provide advantageous effects similar to those in the case of the sufficiently thin pocket according to the comparative example. As apparent from the comparison with FIG. 2, the interface between the P+ impurity diffusion layer 40 and the N+ impurity diffusion layer 20 has an angle of inclination to be more perpendicular to the surface of the substrate than in the comparative example. This allows effective gate electric field strength to be higher in a broader PN junction region. Consequently, the tunneling probability of electrons is increased, and the driving force of the tunnel transistor is improved.

(b) Semiconductor Device Manufacturing Method

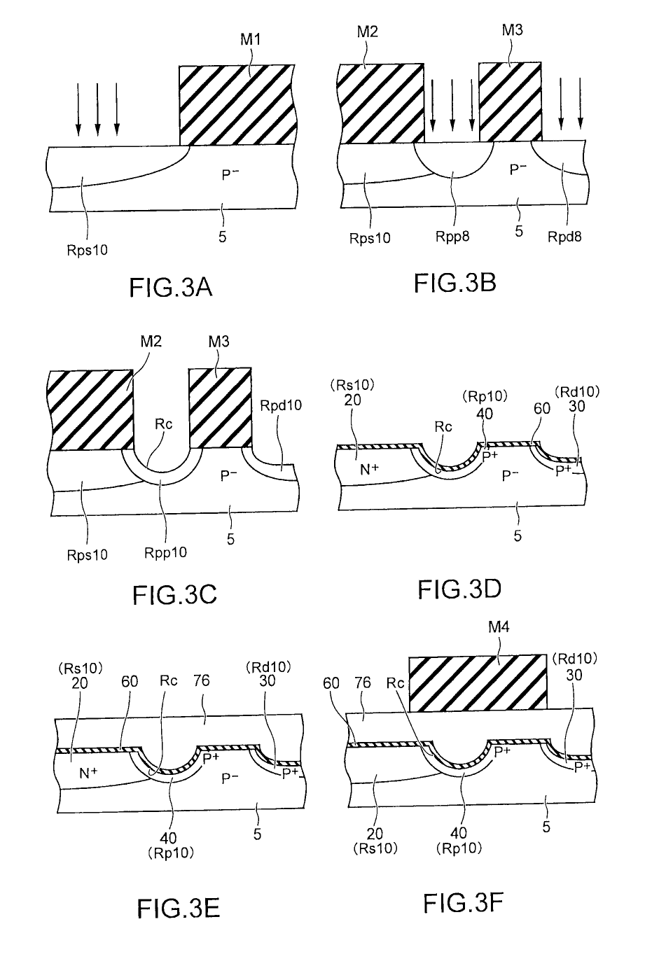

A method of manufacturing the tunnel transistor shown in FIG. 1 is described with reference to schematic sectional views in FIGS. 3A to 3F.

First, as shown in FIG. 3A, a resist mask M1 is formed in a region of the surface layer of a P-substrate 5 except for a source formation region Rps10 by patterning that uses photolithography, and N-type impurity ions are implanted into the source formation region Rps10.

After the whole resist mask M1 is removed, a new resist material is then applied. Resist masks M2 and M3 are formed by patterning that uses photolithography, as shown in FIG. 3B. P-type impurity ions are implanted into a pocket formation region Rpp8 and a drain formation region Rpd8 immediately under a gate.

Furthermore, the pocket formation region Rpp8 is partly removed by dry etching that uses known reactive ion etching, and then surface damages resulting from the dry etching are lessened by hydrogen annealing. Consequently, the pocket formation region is transformed into a region Rpp10 structured to have a recess Rc, as shown in FIG. 3C.

After the resist masks M2 and M3 are removed, an N+ impurity diffusion layer 20 of a source region Rs10, a P+ impurity diffusion layer 40 of a pocket region Rp10, and a P+ impurity diffusion layer 30 of a drain region Rd10 are obtained by activation annealing.

A gate oxide film 60 is then formed by thermal oxidation as shown in FIG. 3D, and polysilicon 76 is deposited thereon as a gate material as shown in FIG. 3E. In this case, the polysilicon 76 is deposited so as to completely fill the recess Rc via the gate oxide film 60.

A resist mask M4 is then formed in a gate formation region by patterning that uses photolithography, as shown in FIG. 3F. The gate and the gate oxide film are selectively cut out by dry etching with the use of the resist mask M4 to form a gate 80 and the gate oxide film 60. Thus, the tunnel transistor shown in FIG. 1 is obtained. In this case, the resist mask M4 is formed so as to cover part of the source region Rs10, the pocket region Rp10, and a region between the pocket region Rp10 and the drain region Rd10.

As described above, according to the present embodiment, the packet has the recess, so that the P+ impurity diffusion layer 40 serving as the pocket can be easily formed.

### (2) Second Embodiment

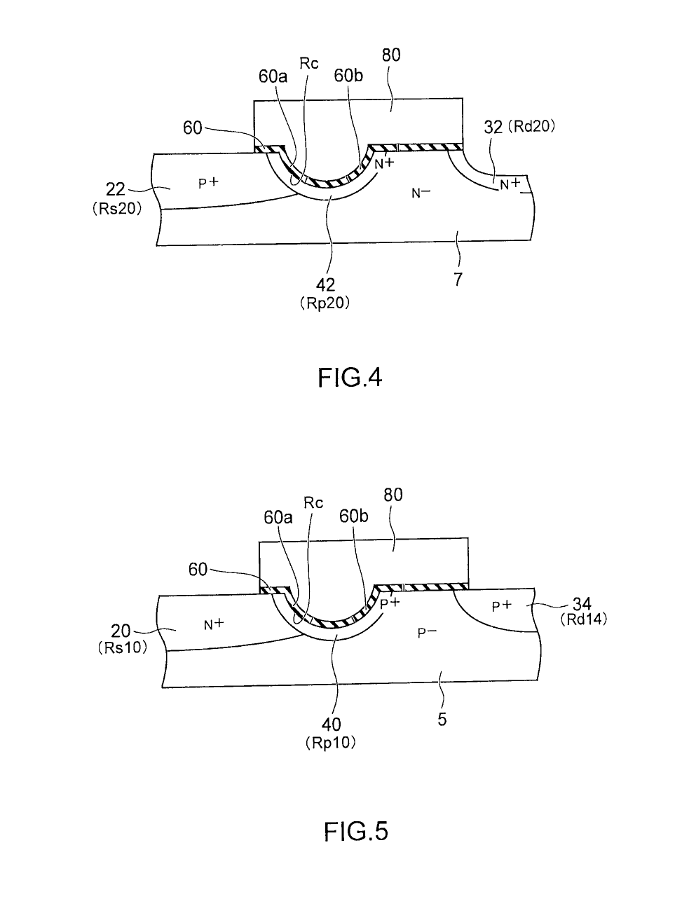

A tunnel transistor according to a second embodiment is shown in a schematic sectional view in FIG. 4. In the present embodiment, the first embodiment described above is applied to a PMIS-type tunnel transistor in which the P-type and N-type of components equivalent to the components in FIG. 1 are reversed.

Specifically, the tunnel transistor shown in FIG. 4 includes an N− type substrate 7, a P+ impurity diffusion layer 22, an N+ impurity diffusion layer 32, an N+ impurity diffusion layer 42, a gate oxide film 60, and a gate 80. The P+ impurity diffusion layer 22 is formed in a source region Rs20 and serves as a source. The N+ impurity diffusion layer 32 is formed in a drain region Rd20 and serves as a drain. The N+ impurity diffusion layer 42 is formed to have a recess structure in a pocket region Rp20 adjacent to the source region Rs20 and serves as a pocket.

In the present embodiment, the P+ impurity diffusion layer 22, the N+ impurity diffusion layer 42, and the N+ impurity diffusion layer 32 correspond to, for example, first to third impurity diffusion layers, respectively. The N-type and the P-type correspond to, for example, first and second conductivity types, respectively.

The characteristics and manufacturing method of the tunnel transistor according to the present embodiment are substantially similar to those in the first embodiment described above except that the conductivity type of impurity ions to be implanted is opposite. Therefore, detailed explanations are not given.

### (3) Third Embodiment

(a) Structure of Semiconductor Device

FIG. 5 is a schematic sectional view of a tunnel transistor according to the third embodiment.

As apparent from the comparison with FIG. 1, the tunnel transistor according to the present embodiment is characterized in that the surface of a P+ impurity diffusion layer 34 serving as a drain is formed to be higher than that of the P+ impurity diffusion layer 30 in FIG. 1 and is therefore substantially flush with the surface of an N+ impurity diffusion layer 20 of a source region Rs10. In the present embodiment, the P+ impurity diffusion layer 34 corresponds to, for example, a third impurity diffusion layer. The configuration of the tunnel transistor according to the present embodiment is substantially the same in other respects as that according to the first embodiment described above.

In the present embodiment, a P+ impurity diffusion layer 40 also has a recess structure. Therefore, the interface between the P+ impurity diffusion layer 40 and the N+ impurity diffusion layer 20 has an angle of inclination to be more perpendicular to the surface of the substrate than in the comparative example described above. This allows effective gate electric field strength to be higher in a broader PN junction region. Consequently, the tunneling probability of electrons is increased, and the driving force of the tunnel transistor is improved.

Moreover, in the present embodiment, the surface of the P+ impurity diffusion layer 34 is substantially flush with the surface of the N+ impurity diffusion layer 20. Thus, the device is improved in planarity, and is enhanced in characteristics accordingly.

(b) Semiconductor Device Manufacturing Method

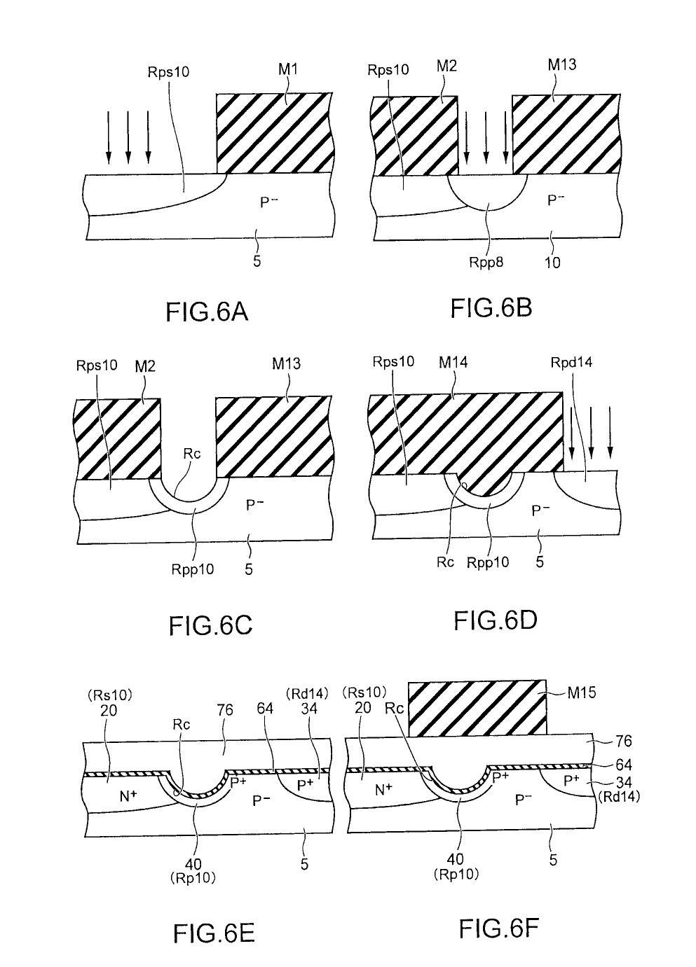

A method of manufacturing the tunnel transistor shown in FIG. 5 is described with reference to FIGS. 6A to 6F.

First, as shown in FIG. 6A, a resist mask M1 is formed by patterning that uses photolithography, and N-type impurity ions are implanted into a source formation region Rps10, as in the first embodiment described above.

After the whole resist mask M1 is removed, a new resist material is then applied. Resist masks M2 and M13 are formed by patterning that uses photolithography, as shown in FIG. 6B. P-type impurity ions are implanted into a pocket formation region Rpp8 immediately under a gate. In contrast with the first embodiment described above, the resist mask M13 is formed so as to also cover a drain region (see the reference number Rpd14 in FIG. 6D) in this process. Thus, ions are not implanted into the drain region Rpd.

Furthermore, the pocket formation region Rpp8 is partly removed by dry etching that uses known reactive ion etching, and then surface damages resulting from the dry etching are lessened by hydrogen annealing. Consequently, the pocket formation region is transformed into a region Rpp10 structured to have a recess Rc, as shown in FIG. 6C.

The resist masks M2 and M13 are then completely removed. As shown in FIG. 6D, a resist mask M14 covering a region except for the drain formation region Rpd14 is formed, and P-type impurity ions are implanted into the drain formation region Rpd14.

After the resist mask M14 is removed, an N+ impurity diffusion layer 20 of a source region Rs10, a P+ impurity diffusion layer 40 of a pocket region Rp10, and a P+ Impurity diffusion layer 34 of a drain region Rd14 are obtained by activation annealing.

A gate oxide film 64 is then formed by thermal oxidation, and polysilicon 76 is deposited thereon as a gate material as shown in FIG. 6E. In this case, the polysilicon 76 is deposited so as to completely fill the recess Rc via the gate oxide film 64.

A resist mask M15 is then formed in a gate formation region by patterning that uses photolithography, as shown in FIG. 6F. In this case, in the present embodiment, the resist mask M15 is formed so as to cover a region ranging from part of the source region Rs10 to part of the drain region Rd14.

The gate and the gate oxide film are then selectively cut out by dry etching with the use of the resist mask M15 to form a gate 80 and a gate oxide film 60. Thus, the tunnel transistor shown in FIG. 5 is obtained.

As described above, according to the present embodiment, the number of processes is increased as compared with the first embodiment. However, a tunnel transistor with further improved device characteristics can be manufactured.

### (4) Fourth Embodiment

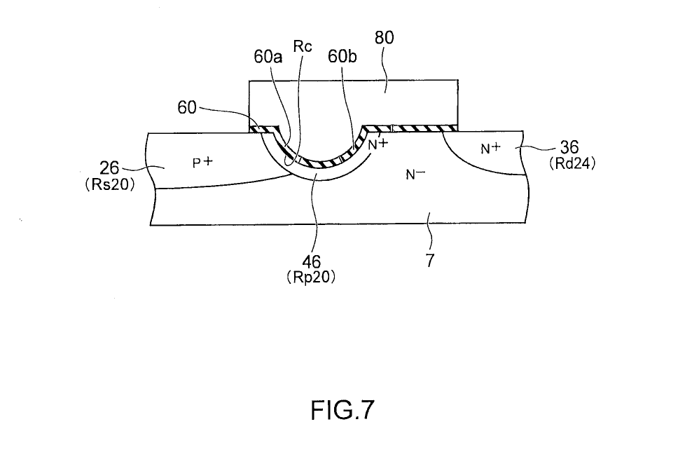

A tunnel transistor according to a fourth embodiment is shown in a schematic sectional view in FIG. 7. In the present embodiment, the third embodiment described above is applied to a PMIS-type tunnel transistor in which the P-type and N-type of components equivalent to the components in FIG. 5 are reversed.

Specifically, the tunnel transistor shown in FIG. 7 includes an N− type substrate 7, a P+ type impurity diffusion layer 26, an N+ impurity diffusion layer 36, an N+ impurity diffusion layer 46, a gate oxide film 60, and a gate 80. The P+ type impurity diffusion layer 26 is formed in a source region Rs20 and serves as a source. The N+ impurity diffusion layer 36 is formed in a drain region Rd24 and serves as a drain. The N+ impurity diffusion layer 46 is formed to have a recess structure in a pocket region Rp20 adjacent to the source region Rs20 and serves as a pocket.

In the present embodiment, the P+ type impurity diffusion layer 26, the N+ impurity diffusion layer 46, and the N+ impurity diffusion layer 36 correspond to, for example, first to third impurity diffusion layers, respectively. The N-type and the P-type correspond to, for example, first and second conductivity types, respectively.

The characteristics and manufacturing method of the tunnel transistor according to the present embodiment are substantially similar to those in the third embodiment described above except that the conductivity type of impurity ions to be implanted is opposite. Therefore, detailed explanations are not given.

Although the drain region is formed after the source region is formed in the tunnel transistor manufacturing method according to the present embodiment described above, the present invention is not limited to thereto. The drain region may be formed first, and then the source region may be formed.

Although the tunnel transistor is formed on the surface of the substrate 5 or 7 in the first to fourth embodiments described above, the present invention is not limited to thereto. It should be understood that the tunnel transistor described above may be formed on a semiconductor layer which is formed in the surface layer of the substrate.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer of a first conductivity type comprising a recess in the surface thereof;
a pocket region of the first conductivity type in the semiconductor layer comprising a part under the surface of the recess;
a source region of a second conductivity type in the semiconductor layer, the source region being located adjacent to the pocket region, the second conductivity type being different from the first conductivity type;
a drain region of the first conductivity type in the semiconductor layer, the drain region being located away from the source region and the pocket region;
a gate insulating film over the surface of the recess, the gate insulating film comprising first and second parts, the first part facing an interface between the source region and the pocket region, the second part facing the first part across the recess; and
a gate electrode configured to fill the recess via the gate insulating film.

2. The semiconductor device of claim 1,
wherein the surface of the drain region is substantially flush with the bottom surface of the recess.

3. The semiconductor device of claim 1,
the surface of the drain region is substantially flush with the surface of the source region.

4. The semiconductor device of claim 1,
wherein the whole pocket region has substantially the same thickness.

5. The semiconductor device of claim 1,
wherein the gate insulating film has a shape protruding toward a substrate so as to correspond to the shape of the recess.

6. The semiconductor device of claim 2,
wherein the drain region has substantially the same thickness as the pocket region.

7. A semiconductor device comprising:
a semiconductor layer of a first conductivity type comprising a recess in the surface thereof;
a pocket region of the first conductivity type in the semiconductor layer comprising a part under the surface of the recess;
a source region of a second conductivity type in the semiconductor layer, the source region being located adjacent to the pocket region, the second conductivity type being different from the first conductivity type;
a drain region of the first conductivity type in the semiconductor layer, the drain region being located away from the source region and the pocket region;
a gate insulating film on the recess in the semiconductor layer, the gate insulating film comprising first and second parts, the first part facing an interface between the source region and the pocket region, the second part facing the first part across the recess; and
a gate electrode on the semiconductor layer via the gate insulating film.

8. The semiconductor device of claim 7,
wherein the surface of the drain region is substantially flush with the bottom surface of the recess.

9. The semiconductor device of claim 7,
the surface of the drain region is substantially flush with the surface of the source region.

10. The semiconductor device of claim 7,
wherein the whole pocket region has substantially the same thickness.

11. The semiconductor device of claim 7,
wherein the semiconductor layer of the first conductivity type is a surface layer of a substrate.

12. The semiconductor device of claim 7, further comprising a substrate on which the semiconductor layer of the first conductivity type is formed.

13. A semiconductor device forming method comprising:
implanting, into a semiconductor layer of a first conductivity type, an impurity of a second conductivity type different from the first conductivity type, and forming a source region;
forming a drain region in the semiconductor layer in a region located away from the source region;
implanting an impurity of the first conductivity type into a part of the semiconductor layer adjacent to the source region;
forming a recess by selectively removing the part of the semiconductor layer into which the impurity of the first conductivity type is implanted; and
forming a gate insulating film and a gate electrode on the recess.

14. The method of claim 13,
wherein the impurity of the first conductivity type is simultaneously implanted into the drain region and the part of the semiconductor layer adjacent to the source region.

15. The method of claim 13,
wherein the impurity of the first conductivity type is separately implanted into the drain region and the part of the semiconductor layer adjacent to the source region.

16. The method of claim 13,
wherein the source region is formed before the drain region.

17. The method of claim 13,
wherein the drain region is formed before the source region.

18. The method of claim 13,
wherein forming the recess further comprises using hydrogen annealing to lessen surface damages of the recess.
